(19) United States
(12) Patent Application Publication
(10) Pub. No.: US 2011/0031378 A1
(43) Pub. Date: Feb. 10, 2011

(54) ELECTROMAGNETIC WAVE RECEPTION DEVICE, IMAGING DEVICE, AND ELECTROMAGNETIC WAVE RECEPTION METHOD

(75) Inventor: Yutaka Hirose, Kyoto (JP)

Correspondence Address: GREENBLUM & BERNSTEIN, P.L.C., 1950 ROLAND CLARKE PLACE, RESTON, VA, 20191, US

(73) Assignee: PANASONIC CORPORATION, Osaka (JP)

(21) Appl. No.: 12/937,157

(22) PCT Filed: Apr. 13, 2009
(86) PCT No.: PCT/JP2009/001691

§ 371 Date: Oct. 8, 2010

(30) Foreign Application Priority Data
Apr. 14, 2008 (JP) 2008-104555

(51) Int. Cl. H01L 27/148; H01L 31/09

(52) U.S. Cl. 250/208.1; 257/222; 257/E31.093; 257/E27.15

(57) ABSTRACT

Provided is an electromagnetic wave reception device capable of being downsized and directly and simply (at least at a room temperature) detecting electromagnetic waves in a wider bandwidth including the terahertz range. The electromagnetic wave reception device that obtains charges according to an electric field of the electromagnetic waves incident on a semiconductor substrate includes: a high charge-density region provided on the semiconductor substrate and having a first charge density; a conductive region covering the high charge-density region via an insulation region; and a low charge-density region provided adjacent to the high charge-density region on the semiconductor substrate and having a second charge density lower than the first charge density, wherein the low charge-density region is connected to a charge detecting circuit that is not illustrated.

### TECHNICAL FIELD

The present invention relates to an electromagnetic wave reception device and an imaging device using the electromagnetic wave reception device.

### BACKGROUND ART

Since the electromagnetic waves have different transmissive and reflection characteristics for an object according to each wavelength (frequency), the detection principles also differ according to each wavelength. The background technology for detecting the electromagnetic waves having different wavelengths will be described hereinafter.

The electromagnetic waves having wavelengths from 0.01 nm to 2 μm correspond to gamma radiation to near infrared radiation, and the photon energy is relatively higher. In order to detect the electromagnetic waves, a semiconductor or an insulator having a band-gap energy smaller than that of the photon energy is irradiated with the electromagnetic waves. Accordingly, an electromagnetic wave reception device referred to as a photo detection element detects the electromagnetic waves as a voltage or a current generated by the electrons or positive holes generated in the semiconductor or insulator.

In particular, digital cameras use image sensors each of which has visible light-sensitive photodiodes arranged in two-dimensional arrays, read charges generated by the light entering each of the photodiodes within a certain period of time, and provide the charges as image signals. Since a photoreceptor and a signal processing unit included in each of the image sensors are formed in the same fine semiconductor processes, the image sensors are readily integrated and downsized.

The electromagnetic waves having long wavelengths from approximately 2 μm to 10 μm (infrared radiation) have smaller photon energy, and electron-hole pairs are excited in photo detection elements by the background heat with a band gap unique to a substance or with a level width artificially formed. Thus, when electromagnetic waves are detected, the photo detection elements have difficulties in obtaining favorable S/N ratios.

Thus, what is used here includes pyroelectric sensors and bolometers. The pyroelectric sensors receive the electromagnetic waves by detecting potential differences occurring due to polarization charges generated from thermal energy corresponding to the incident electromagnetic waves. The bolometers detect voltages or currents generated from resistance variations along with temperature variations.

Generally, materials suitable for the photo detection elements, the pyroelectric sensors, and the bolometers are different from one another. For example, silicon (Si) and Gallium arsenide (GaAs) based materials are suitable for the photo detection elements. Triglycerine sulfate (TGS), PZT, and LiTaO₃ are suitable for the pyroelectric sensors. Germanium (Ge) and silicon are suitable for the bolometers.

Since the suitable materials are different according to the wavelengths of the electromagnetic waves to be detected, technical difficulties lie in implementing both a photo detection function and a function of detecting long-wavelength electromagnetic waves by a single element made of a single material.

Generally, radio receivers are used for receiving electromagnetic waves having wavelengths not smaller than 1 mm (normally referred to as waves, such as millimeter waves, microwaves, and radio waves).

FIG. 1 is a block diagram illustrating an example of a typical radio receiver.

In the radio receiver illustrated in FIG. 1, an antenna 201 made of a conductive material collects radio frequency electromagnetic waves, and transforms the electromagnetic fields into the motion of charges having the same frequency as that of the radio frequency varying electromagnetic fields. After an amplifier circuit 202 amplifies the voltage and current varied along with the transformation, a detection circuit 203 detects the electromagnetic waves.

The detection circuit 203 generates, for example, a DC component by squaring an AC signal, and a processing circuit 204 at the subsequent stage can detect the electromagnetic waves using the DC component. The processing circuit 204 is a circuit that can process a signal having a frequency lower than that of the electromagnetic waves.

Such a radio receiver is used in wireless systems, such as conventional AM/FM radios and mobile phones.

Normally, the wireless systems only receive and reproduce temporal variations of the electromagnetic waves as signals. However, as reported in NPL 1, spatial variations involved in the electromagnetic waves are reproduced by controlling a reception direction using a radio receiver for a millimeter-wave band. In other words, imaging using radio frequency electromagnetic waves is possible.

The conventional radio imaging has a problem of downsizing imaging devices unlike the implementation with the visible light and infrared light, because the antennas are larger than the reception circuits and the integration is difficult.

The electromagnetic waves corresponding to the sub-millimeter wavelengths from approximately several tens of μm to 0.1 mm have frequencies in a range approximately from 0.1 THz to 100 THz, and are referred to as terahertz waves.

The terahertz waves have higher transmissive characteristics for an object, and thus the research and development has been promoted to apply the terahertz waves to imaging devices for a security check, a medical test, a food inspection, and environmental monitoring, for example (NPL 2, and PTL 1 to PTL 3).

The biggest problem for detecting the terahertz waves and imaging is lack of a device that directly and simply detects the terahertz waves.

In other words, when the terahertz waves are detected as photons, the photon energy, for example, amounts to 4 meV at the typical frequency of 1 THz (wavelength of 300 μm) that is equivalent to a temperature not higher than 50K. Thus, the terahertz waves are not completely identifiable from the thermal noise at normal temperatures (approximately 300K).

Thus, narrow band gap materials (NPL 3), a quantum well device (NPL 4), a superconducting device (NPL 5), and others have been reported as photo detection elements for detecting terahertz waves. The photo detection elements are required to operate at very low temperatures where the thermal noise is sufficiently suppressed, and thus handling of these elements is complicated.

Furthermore, the implementation of a radio receiver that receives terahertz waves is currently very difficult, because no electronic device that operates at a speed equivalent to that of the high-frequency electromagnetic waves in the terahertz range received by an antenna has yet been developed.

The highest frequency at which radio receivers receive terahertz waves is currently only within the sub-millimeter wavelength range of approximately one hundred GHz (0.1 THz) at most, even when a high electron mobility transistor (HEMT) whose processing speed is the fastest is used in an amplifier circuit and a detection circuit.

The single device reported as possibly detecting the terahertz waves pyroelectrically is a pyroelectric sensor made of a vanadium oxide (VOx) that has been developed for detecting infrared radiation. NPL 6 reports the discovery of the pyroelectric sensor sensitive even in the terahertz range, and the application as a terahertz imaging sensor.

However, since the pyroelectric sensor has less detection sensitivity to higher frequency than to near infrared radiation as described above, it is not suitable for receiving electromagnetic waves in a wider bandwidth.

Since imaging through direct detection of terahertz waves is difficult, the most common and conventionally reported technique for detecting terahertz waves and terahertz imaging is based on a Time Domain Terahertz Spectroscopy (THz-TDS) technique.

The THz-TDS technique is to generate terahertz-wave pulses by exciting a terahertz-wave source using a femtosecond laser light source that generates ultrashort light pulses as an excitation source, to irradiate photoconductive elements and field effect modulators with the generated terahertz-wave pulses in synchronization with probe light pulses derived from the same femtosecond laser light, and to detect the variations of the probe light by a photo detector.

FIG. 2 is a block diagram illustrating an example of a basic structure of an imaging device using the THz-TDS.

A femtosecond laser light source 211 generates ultrashort light pulses approximately having a pulse width of 100 fs, and a beam splitter 212 bifurcates the ultrashort light pulses into a pump light 213 and a probe light 214. The pump light 213 passes through an optical delay line 215 and is reflected from a mirror 216. Then, the pump light 213 is incident on a photoconductive switch 217 that has been biased by a certain voltage that is a terahertz-wave source, so that the terahertz waves are irradiated from the incident surface of the photoconductive switch 217 and a surface opposite to the incident surface.

A test object 218 is irradiated with the generated terahertz waves, and a transmission component 219 is converged by a lens 220 made of polyethylene. After the transmission component 219 passes through a half mirror 221 made of silicon (Si), it is incident on an electric field modulator 222 in such a manner that a transmitted electromagnetic-wave image of the test object 218 is formed.

The light path of the probe light 214 is changed by a mirror 223, and a beam expander 224 expands a beam radius of the probe light 214. Then, the probe light 214 is reflected from the half mirror 221 as a probe light 225, and the probe light 225 is incident on the electric field modulator 222 simultaneously when the transmission component 219 of the terahertz waves is incident thereon.

The terahertz waves functioning as a modulation electric field for the probe light 225 modulate the polarization component of the probe light 225. Thus, the electric intensity of the terahertz waves is detected by a photo detector 227 as modulated amounts in light transmission amounts of the probe light 225 transmitted from a light polarizer 226.

Since the terahertz waves and the probe light are spatially extensive, using an image sensor made of an array of two-dimensional photodiodes as a photo detector allows for imaging two-dimensional information of the test object 218 (NPL 7).

However, there are many problems in putting the terahertz waves into practical use with the conventional techniques. The problems includes incapability of its direct reception, complexity of the structure of the reception device, upsizing of the device, and high cost of the device due to the THz-TDS technique using a femtosecond laser pulse laser.

There is another report suggesting the possibility of direct detection of terahertz waves.

NPL 8 reports the principle of a conventional field effect transistor for millimeter waves. Even when a critical operating frequency of the field effect transistor is lower than 1 THz, in the case where the terahertz waves can be coupled to channel charges, the channel charges are excited by plasma oscillations in a high-frequency electromagnetic field. The attenuation energy can be detected as a DC voltage at a drain terminal. Here, the critical operating frequency is defined by an electron drift velocity. Meanwhile, NPL 9 is an experimental report on direct reception of terahertz waves based on the principle.

The reports in NPLs 8 and 9 show that electron density immediately under a gate of a field effect transistor can be modulated in a gate length direction by terahertz waves. The reports also prove that detection of a modulated amount of the electron density as, for example, variations in DC voltages according to the boundary conditions in a drain terminal can lead to direct detection of terahertz waves.

However, the reports fail to disclose any specific means to excite channel charges immediately under the gate with high-frequency electromagnetic waves in the terahertz range. The experiment reported in NPL 9 only points out the possible implementation of plasmon excitation in the channel charges using parasitic wires, such as a wire bond as an antenna by coupling the incident terahertz waves to channel charges with a low degree of efficiency.

The incident terahertz waves can be coupled to the channel charges with the same structure as that of the conventional radio receiver in FIG. 1, that is, the structure in which an antenna having reception sensitivity to the terahertz waves is coupled to a gate of a field effect transistor through a matching circuit.

However, since the antenna is much larger than the field effect transistor that is a detection element in such a structure as in the structure of a millimeter wave imaging device, the integration of the antenna onto a single substrate is difficult.

The difficulty arises because of extreme differences between the wavelengths of terahertz waves to be received (approximately 10 μm to 1000 μm) and a plasmon that determines a cavity length of a receiver, more generally speaking, a typical length of a spatial density distribution of charges (approximately up to 0.5 μm).

Furthermore, since with such a structure, the antenna and the field effect transistor function as resonators that respectively operate only in bands centering on particular frequencies as with the conventional radio receiver, the operations of the antenna and the field effect transistor in a wide frequency range cannot be expected. In particular, the difficulty lies in the application of the antenna and the field effect transistor to receive electromagnetic waves categorized in a different frequency range.

Thus, solutions to these two problems, that is, (i) efficient coupling of the electromagnetic waves to the modulation in an electron density distribution and (ii) widening the operating frequency range may be beneficial to the implementation of direct reception of the electromagnetic waves in a wider bandwidth including the terahertz range.

Speaking of a generator of terahertz waves (terahertz emitter), NPL 10 reports the technique related to the aforementioned problems.

FIG. 3 schematically illustrates a structure of a terahertz emitter disclosed in NPL 10.

The terahertz emitter includes a source 2202 and a drain 2203 on a substrate 2201, and two kinds of gates that have different gate lengths and are disposed at periodical intervals on an electron donor layer 2204 between the source 2202 and the drain 2203. The two kinds of gates are (i) gates 2251, 2252, 2253, and others, and (ii) gates 2261, 2262, 2263, and others.

With such a structure, two dimensional electron gas 2207 is formed directly underneath the electron donor layer 2204. With the application of different DC biases to the different kinds of gates, the electron density is modulated under the two kinds of gates and in a region between the gates.

Furthermore, with the irradiation of laser light 2208 on the underside of the emitter, electron-hole pairs are generated, and only the generated electrons are injected to a surface region of the emitter where the electric field has been modulated by the gate bias. Then, the plasmons derived from different electron density distributions and having different frequencies are generated under each of the gates, according to the electric field of the applied DC bias.

The coupling of the electromagnetic field associated with these plasmons to the periodical gates yields a radiation field that produces the terahertz radiation vertically in a gate length direction. The terahertz waves generated due to different electron density distributions under each of the gates are in a wider bandwidth and have different wavelengths.

Thus, the well-known fact is that the terahertz emitter produces the electromagnetic radiation including different wavelength components in a direction vertical to a modulation direction of the electron density distributions, with the coupling of the modulated electron density distributions given by the electric field of the DC bias.

### [Citation List]

### [Patent Literature]

### [PTL 1]

### Japanese Unexamined Patent Application Publication No. 2002-5828

### [PTL 2]

### Japanese Unexamined Patent Application Publication No. 2004-20504

### [PTL 3]

### Japanese Unexamined Patent Application Publication No. 2005-37213

### [Non Patent Literature]

### [NPL 1]

### Hirose, et al., IEICE Technical Report, ED2006-190 (2006-12), The Institute Of Electronics Information And Communication Engineers, (2006).

### [NPL 2]

### Withawat Withayachumnankul et al., Proceedings of the IEEE, Vol. 95, No. 8, pp. 1528-1558, IEEE, (2007).

### [NPL 3]

Toyoaki Ohmori (translation supervisor), Chiaki Hirose (translator), “Translation of Terahertz Sensing Technology Volume 1, Electronic device and Advanced System Technology”, p. 26, II. 14-15, NTS Inc., (2006).

### [NPL 4]

### Fuse, et al., IEICE Technical Report, ED2006-192 (2006-12), The Institute Of Electronics Information And Communication Engineers, (2006).

### [NPL 5]

### Taino, et al., IEICE Technical Report, ED2006-192 (2006-12), The Institute Of Electronics Information And Communication Engineers, (2006).

### [NPL 6]

### A. W. M. Lee and Q. Hu, Optics Letters/Vol. 30, No. 19, pp. 2563-pp. 2565, Optical Society of America, (2005).

### [NPL 7]

F. Miyamaru, T. Yonera, M. Tani, and M. Hangyo, Japanese Journal of Applied Physics, Vol. 43, No. 4A, pp. L489-L491, The Japanese Society of Applied Physics, (2004).

### [NPL 8]

### M. Dyakonov and M. Shur, IEEE Transaction on Electron Devices, Vol. 43, No. 3, pp. 380-387, IEEE, (1996).

### [NPL 9]

### R. Tauk, et al., Applied Physics Letters, Vol. 89, 253511, American Institute of Physics, (2006).

### [NPL 10]

### T. Otsuji, et al., Applied Physics Letters, Vol. 89, 263502, American Institute of Physics, (2006).

### SUMMARY OF INVENTION

### Technical Problem

However, unknown is a favorable structure of an electromagnetic wave reception device that can directly receive electromagnetic waves in a wider bandwidth including the terahertz range, achieve effective coupling of the incident electromagnetic waves to the modulated electron density distributions, and detect the modulated amounts of the electron density distributions.

The following describes problems when a single device receives the electromagnetic waves in a wider frequency range and performs imaging using the conventional technique.

(1) The single device cannot receive different kinds of electromagnetic waves that belong to both frequency ranges in which the photon energies are not smaller than and not larger than the band-gap energy.

(2) The single device cannot directly and simply detect the electromagnetic waves in which the photon energy is not larger than the band-gap energy and the frequency range is the terahertz range.

(3) When the electromagnetic waves whose photon energy is not larger than the band-gap energy are detected as radio waves, the difficulty lies in the implementation of a downsized imaging device because the antenna included in the device is much larger than other devices included therein.

The present invention has been conceived under these circumstances, and has an object of providing (i) an electromagnetic wave reception device capable of being downsized and directly and simply (at least at a room temperature) detecting the electromagnetic waves in a wider bandwidth including the terahertz range, (ii) an imaging device using the electromagnetic wave reception device, and (iii) an electromagnetic wave reception method.

### Solution to Problem

In order to solve the problems, the electromagnetic wave reception device according to an aspect of the present invention is an electromagnetic wave reception device that obtains charges according to an electric field of electromagnetic waves incident on a semiconductor substrate, and the device includes: at least one first region provided on the semiconductor substrate and having a first charge density; a conductive region covering the first region via an insulation region; and at least one second region provided adjacent to the first region on the semiconductor substrate and having a second charge density lower than the first charge density, wherein the second region is connected to a charge detecting circuit.

With such a structure, when the electromagnetic waves reach the electromagnetic wave reception device, a fringe electric field is formed at a fringe of the conductive region with the electric field component vertical to a boundary between the first region and the second region on a main surface of the semiconductor substrate. The electric field component is included in the electromagnetic waves immediately before the electromagnetic waves reach the electromagnetic wave reception device. The formed fringe electric field is an electric field vertical to the main surface of the semiconductor substrate, and forms the spatial density distribution of charges coupled to the high-density charges in the first region.

With the fringe electric field, the charges in the first region overflow to the second region. The charges overflowing from the first region to the second region rarely flow back to the first region because of the difference in the charge density between the first region and the second region. The charges are carried inside the semiconductor substrate with the drift electric field on a surface of the second region, and are detected by the charge detecting circuit connected to the second region.

Since the electromagnetic wave reception device detects the incident electromagnetic waves as described above, when detecting in particular the terahertz waves, unlike the case where the terahertz waves are detected as photons, there is no need to place the electromagnetic wave reception device at a lower temperature, which substantially facilitates the usage of the device. Furthermore, the electromagnetic wave reception device can be downsized, because it does not use any antenna for receiving the terahertz waves as radio waves and the size solely depends on the typical length of the spatial density distribution of charges. Thereby, since the dependency of the sensitivity on a frequency according to a length of the antenna is eliminated, the present invention allows for the operation of the electromagnetic wave reception device in a wider frequency range.

Furthermore, a thickness of the conductive region may be greater than a skin depth of the electromagnetic waves incident on the conductive region.

Such a structure prevents the electromagnetic waves from reaching the first region through the conductive region while the electric field component in the direction of the main surface of the semiconductor substrate is maintained, and couples the charges in the first region to the fringe electric field in the vertical direction with a higher degree of efficiency.

Furthermore, a potential well for charges in the first region may be formed in the second region.

With such a structure, the charges overflowing from the first region to the second region are confined in the potential well in the second region, so that the charges can be efficiently collected and the electromagnetic waves can be received at a higher S/N ratio.

Furthermore, the charges in the first region may have a polarity opposite to a polarity of majority carriers in the second region, and majority carriers in the potential well may have a polarity identical to the polarity of the charges in the first region.

Such a structure is suitable for forming the potential well in the second region. Furthermore, when the electromagnetic waves are not incident, a p-n junction formed in a boundary between the first region and the second region separates the two regions. The p-n junction is also useful for restricting the transferring of charges.

Furthermore, the conductive region may be connected to a variable voltage source.

With such a structure, the first region can be maintained at a higher density. As a result, the reception sensitivity can be improved with more overflowing of charges.

Furthermore, a plurality of the first regions and a plurality of the second regions may be alternately arranged, the conductive region may be disposed on each of the first regions, and the second regions may be connected to the charge detecting circuit.

With such a structure, detection of electrons overflowing from multiple boundaries between the first regions and the second regions reduces the influence of, for example, scattering of electrons in the charge density distribution, increases the intensity of signals, and increases the S/N ratio upon reception of the electromagnetic waves.

Furthermore, the first region may have a width half a wavelength of a plasmon formed by the charges in the first region, in a direction perpendicular to a boundary with the second region.

With such a structure, the plasmon generated in the first region forms standing waves. Accordingly, the electric field distribution vertical to the main surface of the semiconductor substrate also forms standing waves. The electric field distribution occurs between the first region and the underside of the conductive region. At the fringe of the conductive region, the incident electromagnetic waves are always coupled to the charges in the first region via the fringe electric field. In other words, the fringe satisfies a free end boundary condition.

Thus, the charge plasmon immediately under the fringe of the conductive region functions as a free end, and the variations in the charge plasmon are maximized. In other words, the amount of charges injected into the second region can be maximized, and the electromagnetic waves can be received at a higher S/N ratio.

Furthermore, the first region and the second region may be adjacent to each other at boundaries extending in different directions.

With such a structure, when the incident electromagnetic waves include polarized-wave components having different directions, charges overflow from boundaries vertical to the respective polarized waves to the second region with the polarized-wave components having the corresponding directions. Thereby, the electromagnetic waves can be detected.

Furthermore, two of the boundaries may be perpendicular to each other.

With such a structure, the electromagnetic waves including the polarized-wave components in any direction can be received.

The present invention can be implemented not only as such an electromagnetic wave reception device but also as an imaging device and an electromagnetic wave reception method.

### ADVANTAGEOUS EFFECTS OF INVENTION

The electromagnetic wave reception device according to the present invention generates a fringe electric field at a fringe of a conductive region on the semiconductor substrate with the electromagnetic waves incident on the conductive region, transfers, between two regions having different charge densities on the semiconductor substrate, the charges with the fringe electric field generated at the fringe of the conductive region, and detects the transferred charges.

Thus, the three problems in the conventional techniques of the electromagnetic wave reception device and the imaging device that is an application of the electromagnetic wave reception device can be solved at the same time. Furthermore, a single device can receive both electromagnetic waves having photon energy not smaller than the band-gap energy and electromagnetic waves having energy smaller than the band-gap energy. Furthermore, the downsized imaging device in which an electromagnetic wave reception unit and a detection circuit are integrated on the same semiconductor substrate can be implemented.

Furthermore, in the imaging device according to the present invention, the electromagnetic wave reception device that receives electromagnetic waves for each pixel is extremely smaller, and the size of a conductive region that couples the electromagnetic waves to charges is approximately identical to those of circuit elements in a receiver. Thus, the integrated and downsized electromagnetic wave imaging device can be implemented.

### BRIEF DESCRIPTION OF DRAWINGS

FIG. 1 is a block diagram illustrating an example of a typical radio receiver.

FIG. 2 is a block diagram illustrating an example of a conventional terahertz imaging device.

FIG. 3 schematically illustrates a structure of a conventional terahertz emitter.

FIG. 4 schematically illustrates an example of a structure of an electromagnetic wave reception device according to Embodiment 1 in the present invention.

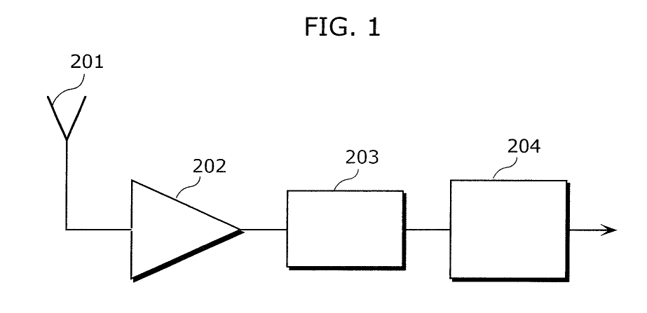

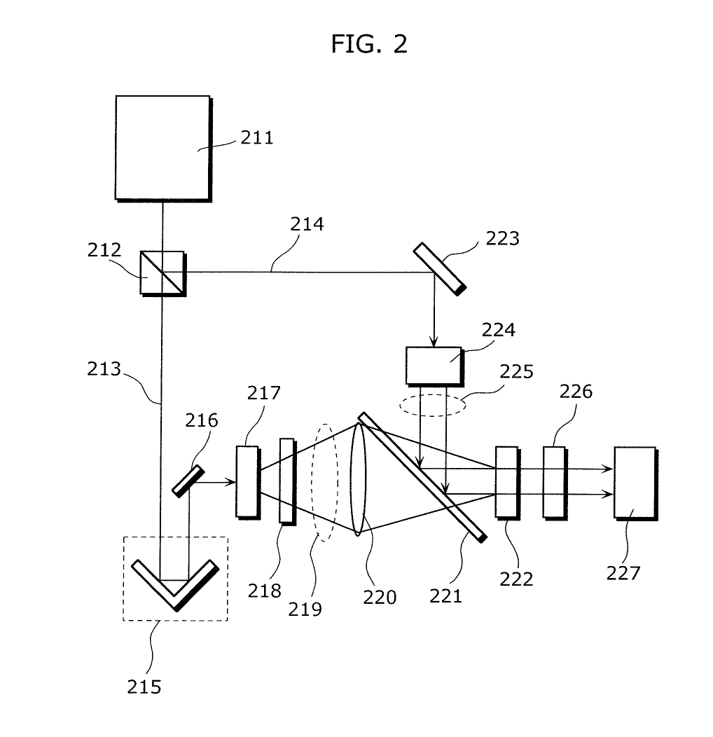

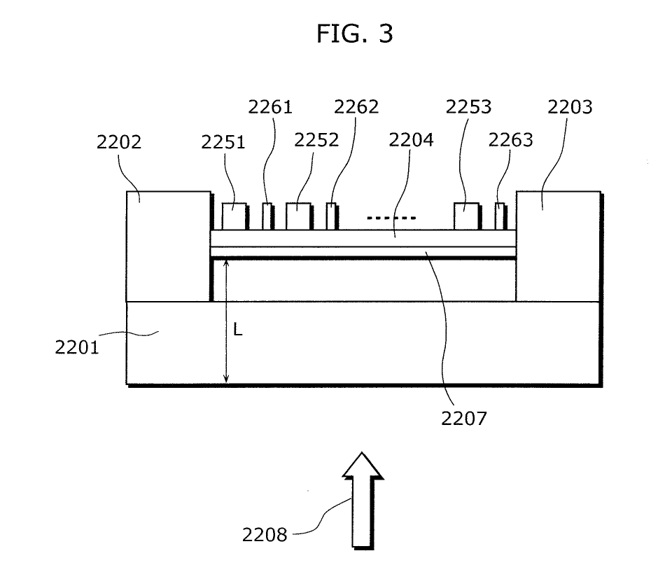

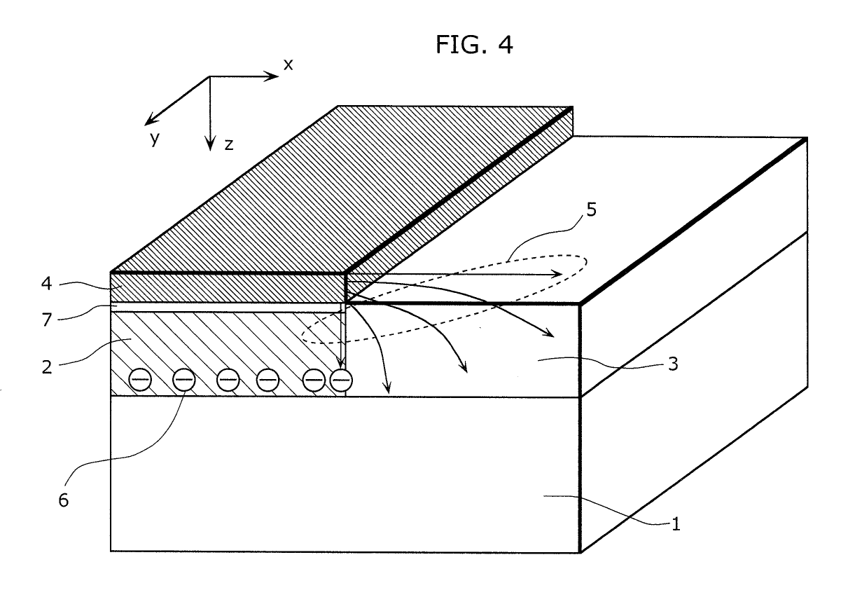

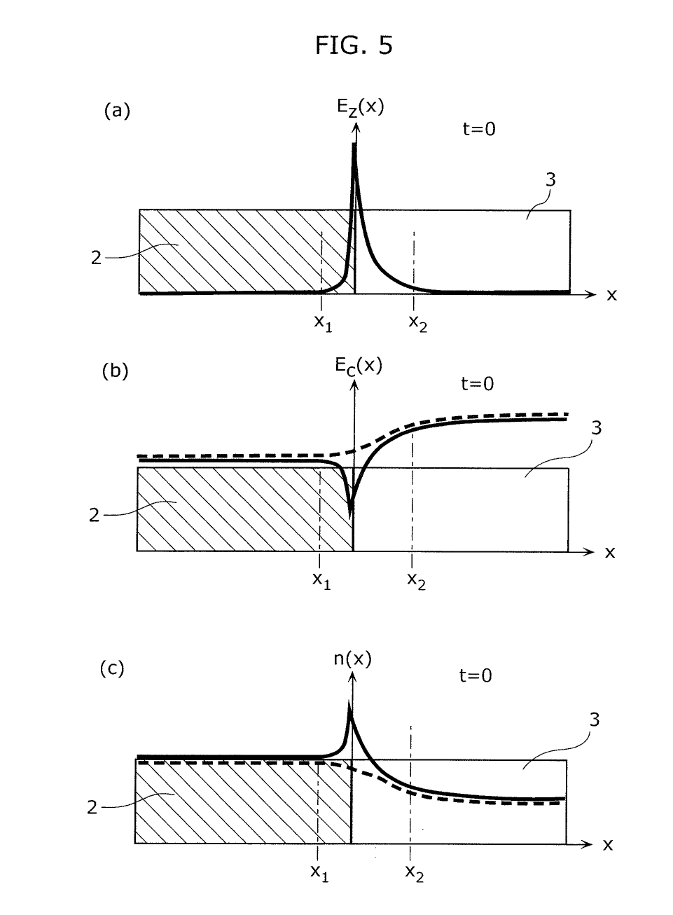

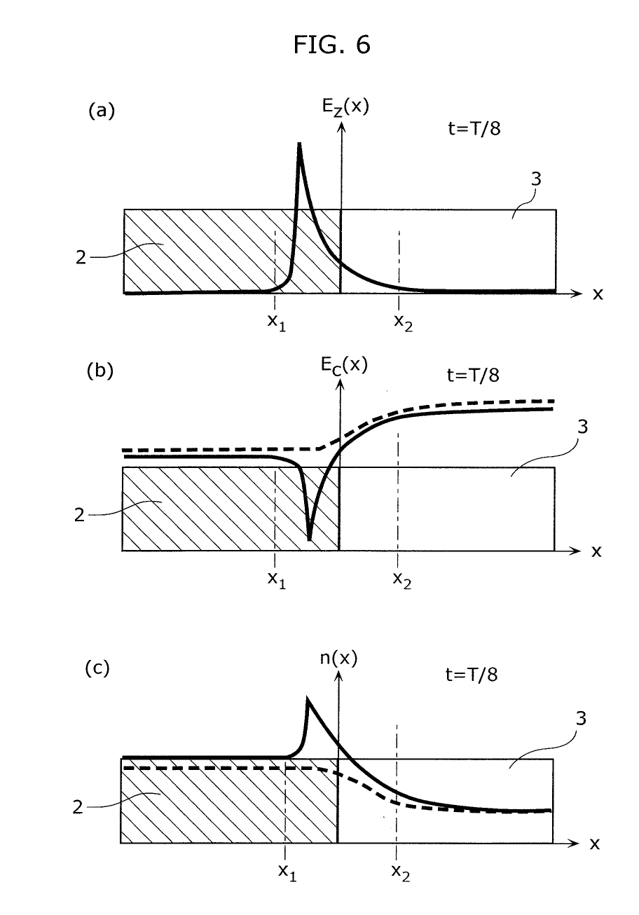

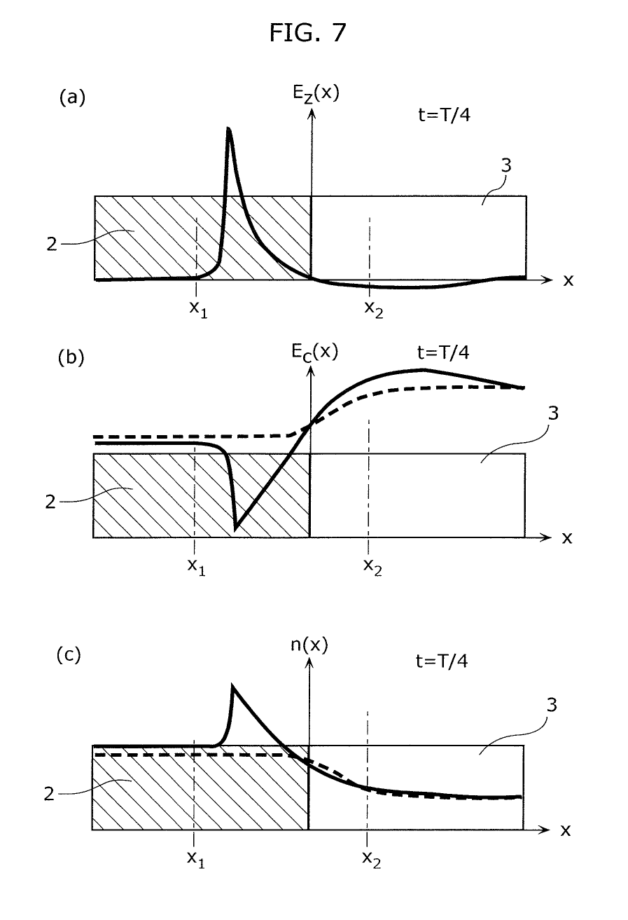

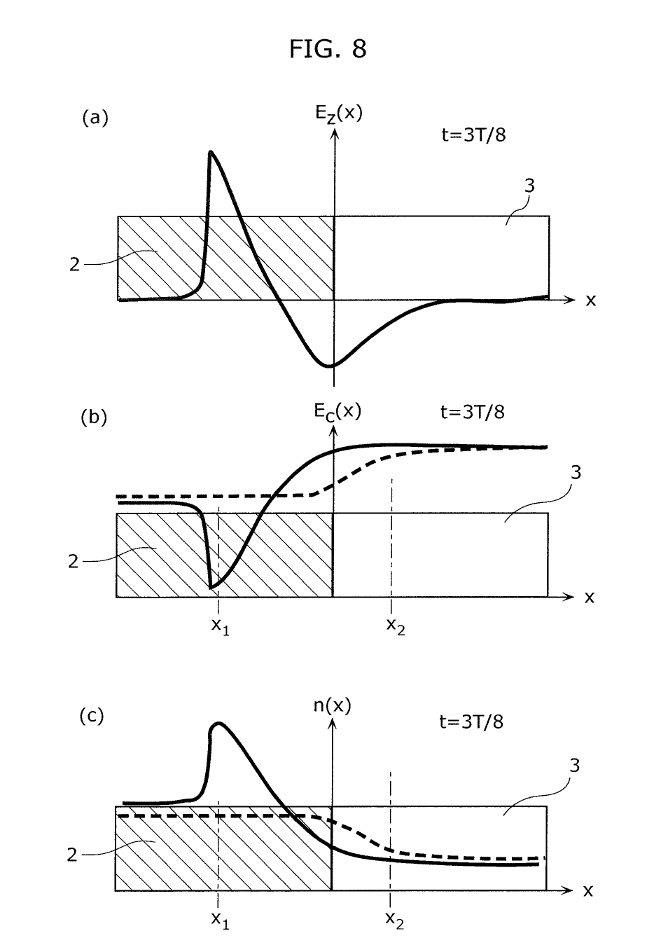

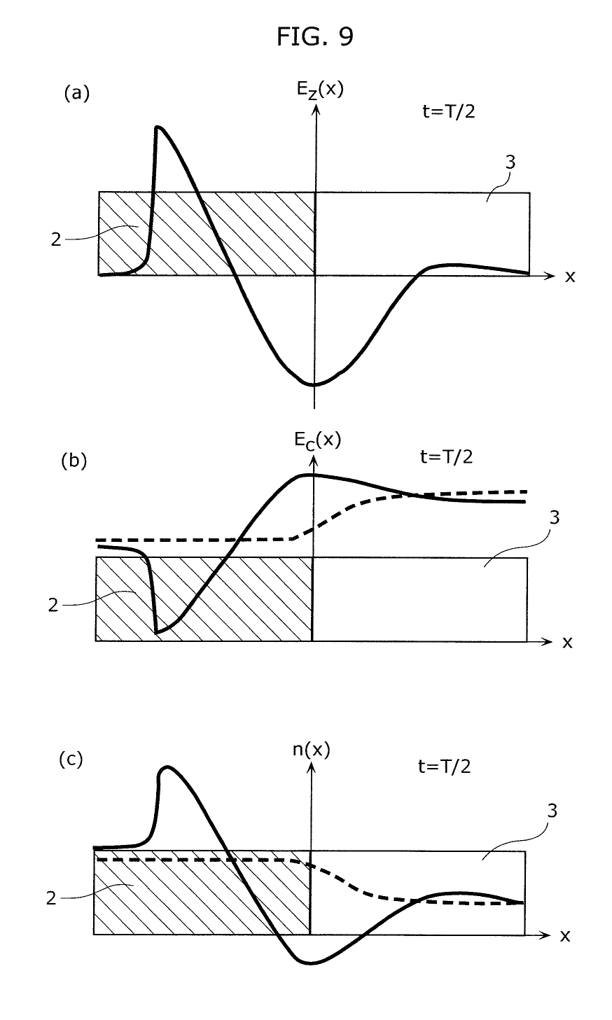

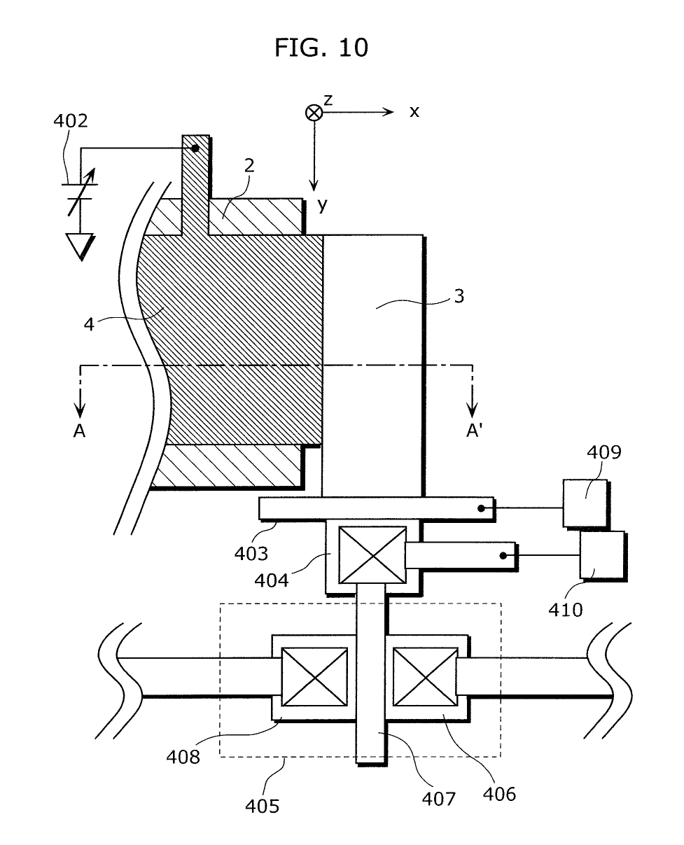

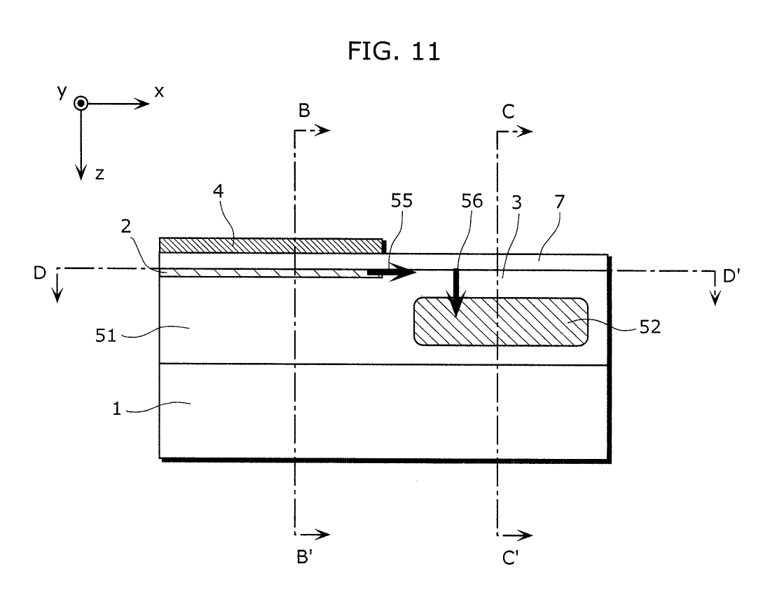

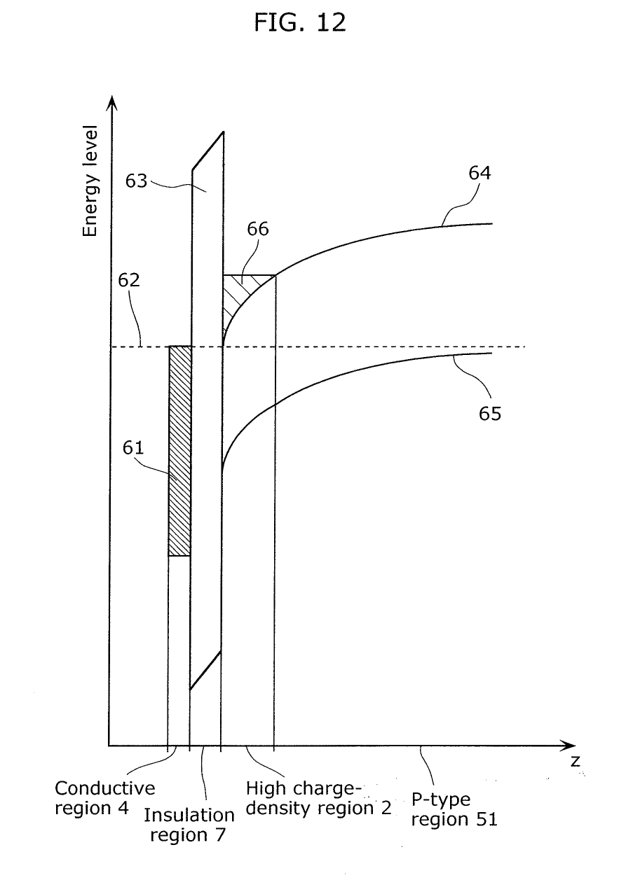

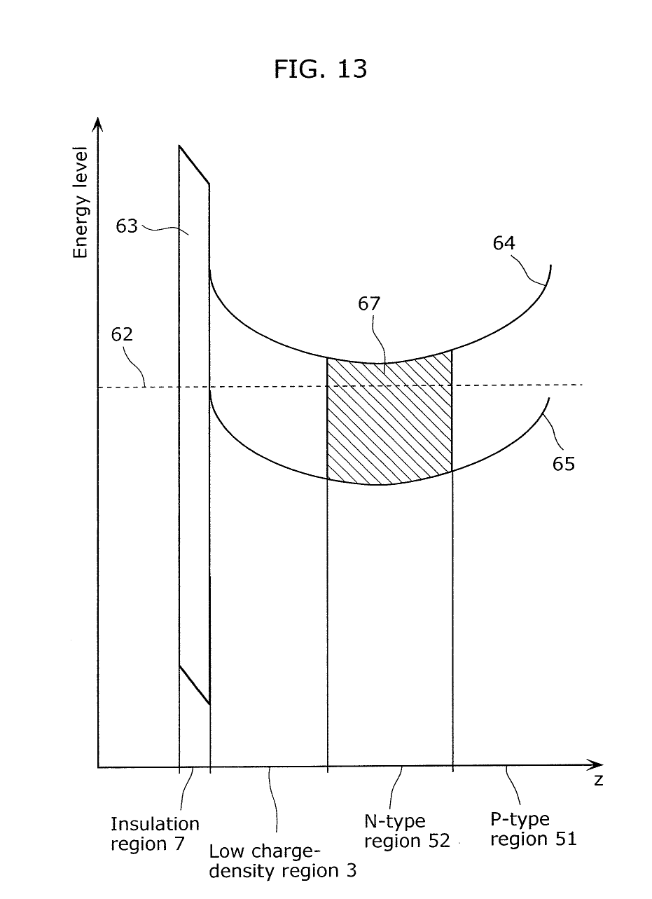

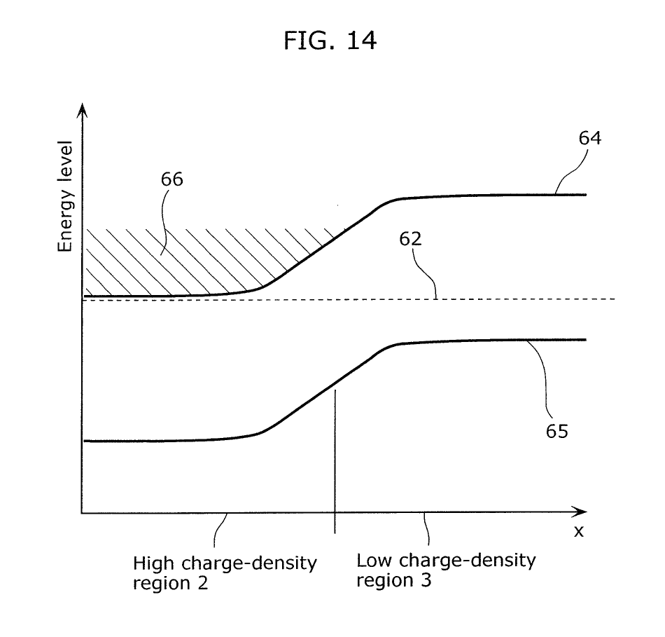

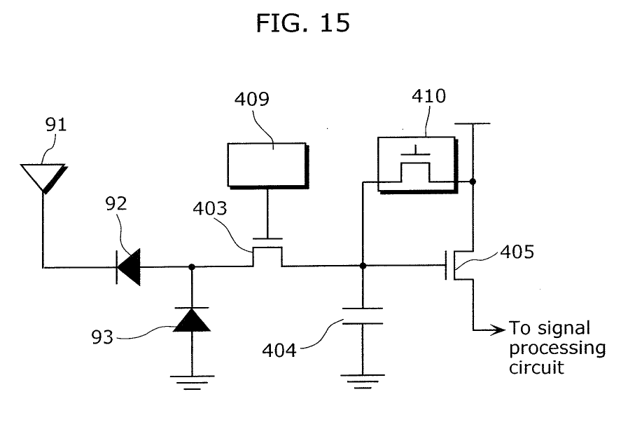

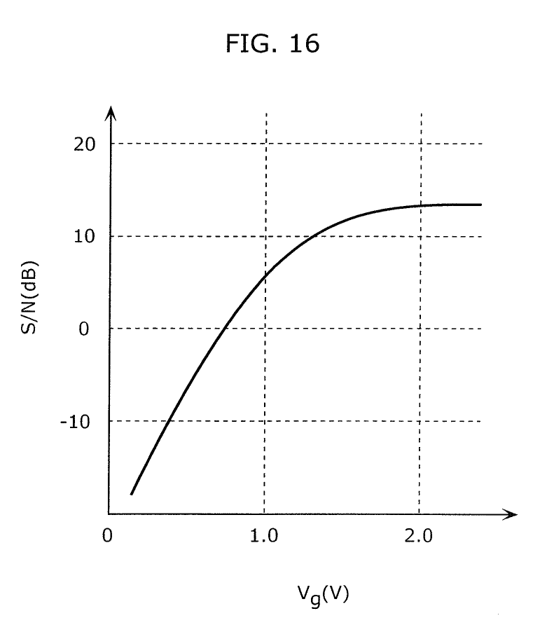

(a) to (c) in FIG. 5 show respective graphs of a fringe electric field, an energy level of electrons, and a distribution of an electron density immediately after the electromagnetic waves are incident.

(a) to (c) in FIG. 6 show respective graphs of a fringe electric field, an energy level of electrons, and a distribution of an electron density at t=T/8.

(a) to (c) in FIG. 7 show respective graphs of a fringe electric field, an energy level of electrons, and a distribution of an electron density at t=T/4.

(a) to (c) in FIG. 8 show respective graphs of a fringe electric field, an energy level of electrons, and a distribution of an electron density at t=3T/8.

(a) to (c) in FIG. 9 show respective graphs of a fringe electric field, an energy level of electrons, and a distribution of an electron density at t=T/2.

FIG. 10 illustrates a top view of a layout example of an electromagnetic wave reception device on a semiconductor substrate according to Embodiment 2 in the present invention.

FIG. 11 is a cross-section view illustrating a section A-A′ of the electromagnetic wave reception device.

FIG. 12 illustrates a band diagram in a section B-B′ of the electromagnetic wave reception device.

FIG. 13 illustrates a band diagram in a section C-C of the electromagnetic wave reception device.

FIG. 14 illustrates a band diagram in a section D-D′ of the electromagnetic wave reception device.

FIG. 15 is an equivalent circuit diagram illustrating the functional structure of the electromagnetic wave reception device in comparison with the conventional technique.

FIG. 16 is a graph showing a dependency of an S/N ratio of a reception signal to a bias voltage, in the electromagnetic wave reception device.

FIG. 17 illustrates a top view of a layout example of an electromagnetic wave reception device on a semiconductor substrate according to Embodiment 3 in the present invention.

FIG. 18 illustrates a top view of a layout example of an electromagnetic wave reception device on a semiconductor substrate according to Embodiment 4 in the present invention.

FIG. 19 illustrates a top view of a layout example of an electromagnetic wave reception device according to Embodiment 5 in the present invention.

FIG. 20 is a block diagram illustrating a functional structure of an imaging device according to Embodiment 6 in the present invention.

FIG. 21 is a graph showing a wavelength dependency of the incident electromagnetic waves to an S/N ratio of an output signal in the imaging device.

### DESCRIPTION OF EMBODIMENTS

### Embodiment 1

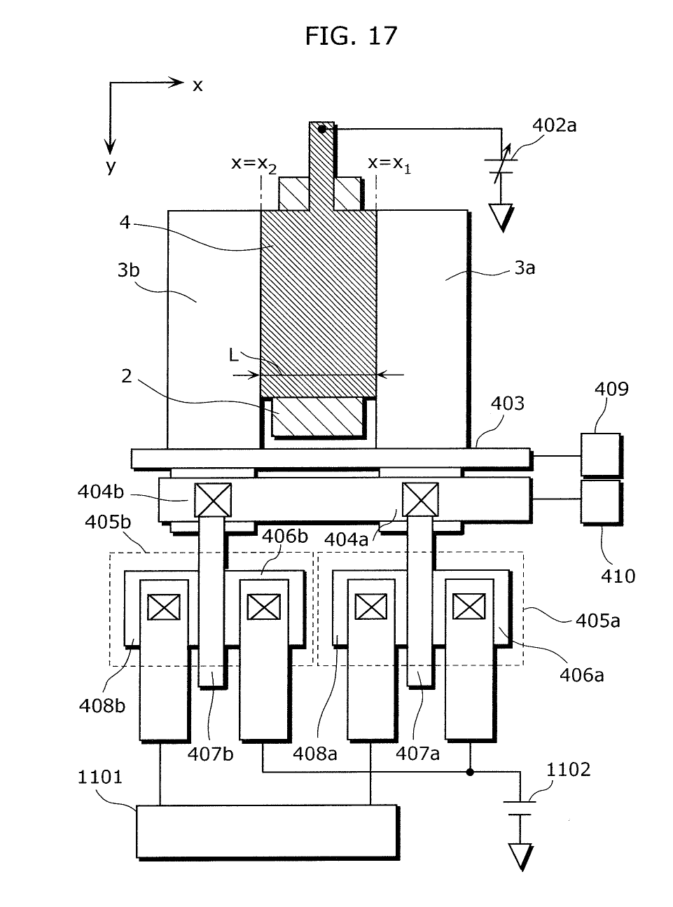

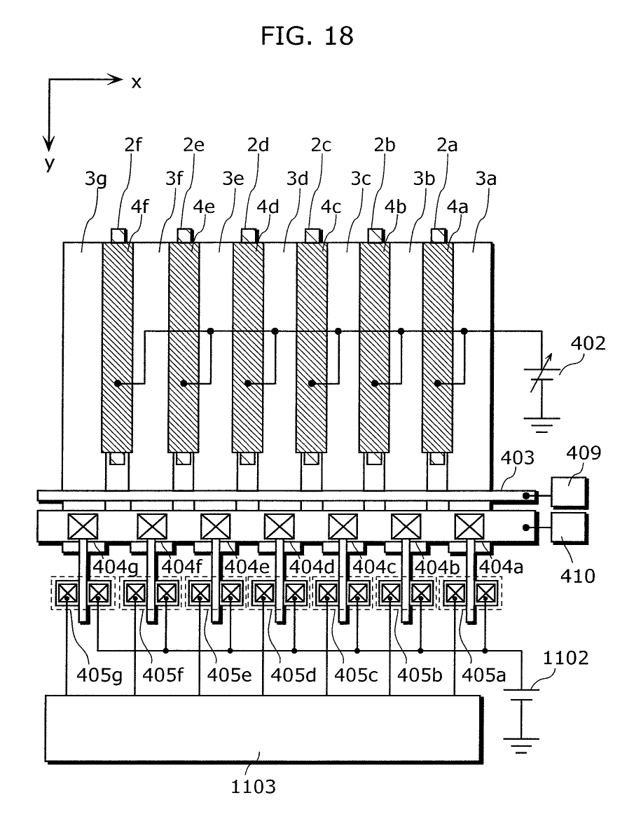

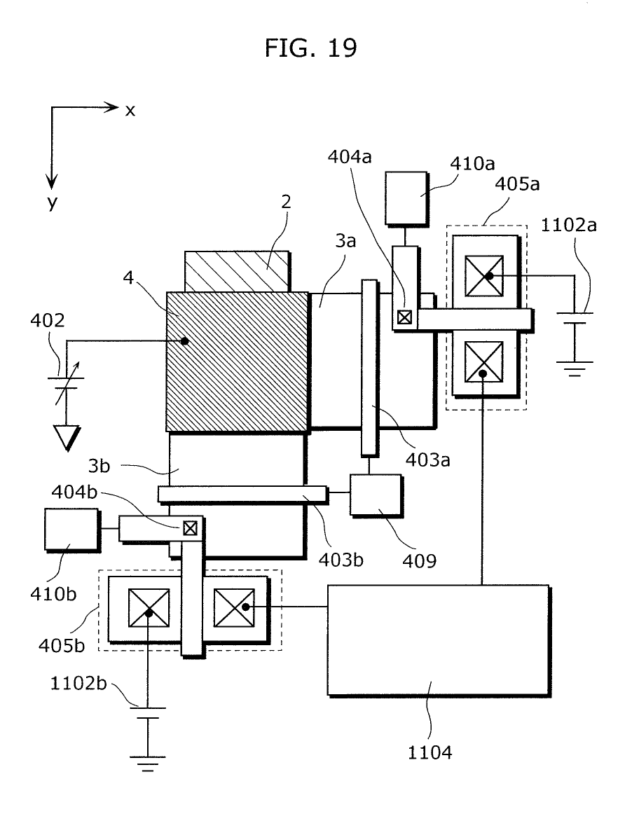

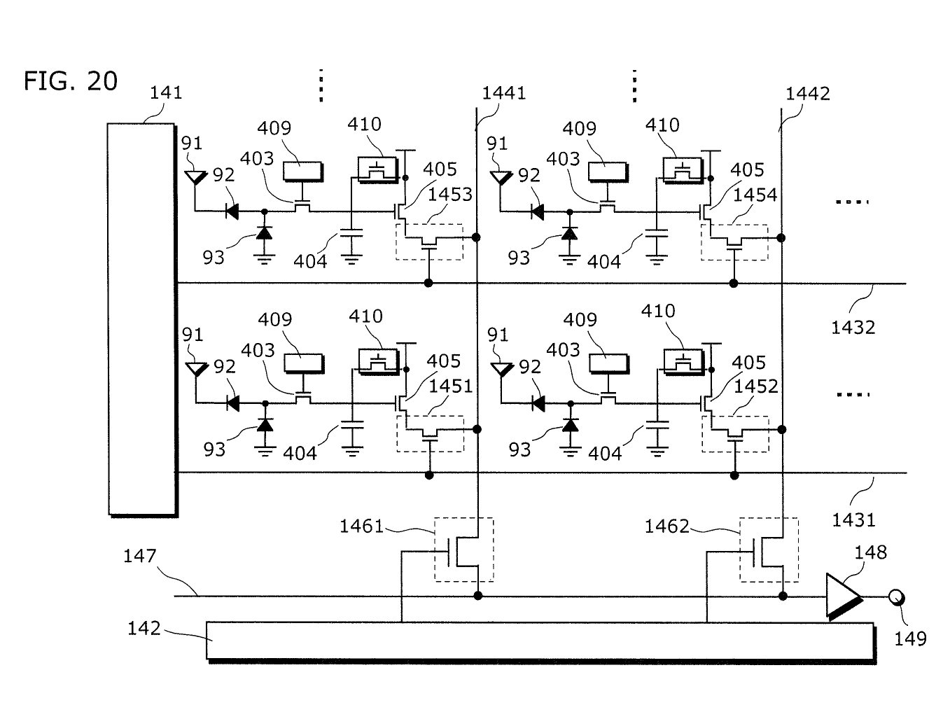

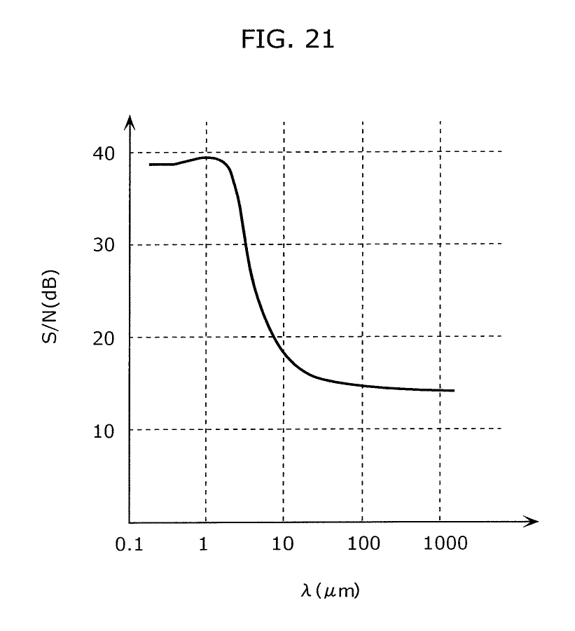

An electromagnetic wave reception device according to Embodiment 1 in the present invention will be described with reference to FIGS. 4 to (a) to (c) in FIG. 9. Embodiment 1 describes an electromagnetic wave reception device having a structure at least required for performing the operations unique and fundamental to the present invention.

FIG. 4 schematically illustrates an example of a structure of the electromagnetic wave reception device according to Embodiment 1. The directions of X, Y, and Z are defined in FIG. 4 for convenience of the explanation.

The electromagnetic wave reception device includes a high charge-density region 2 and a low charge-density region 3 that are adjacently formed with a boundary extending in a Y direction on a semiconductor substrate 1, and a conductive region 4 on the high charge-density region 2 via an insulation region 7. Here, charges are assumed to be electrons.

The high charge-density region 2 and the low charge-density region 3 are examples of a first region and a second region according to the present invention, respectively.

Although there is no limitation on a method of setting a difference in the density between the high charge-density region 2 and the low charge-density region 3, for example, the difference in the density between the two regions may be controlled by a difference in impurity concentration to be injected to each of the high charge-density region 2 and the low charge-density region 3.

As described in Embodiment 2, since normally there is no difference in the density between the high charge-density region 2 and the low charge-density region 3, a region where the charges are more concentrated than the low charge-density region 3 may be generated within the high charge-density region 2 with the application of the bias voltage between the semiconductor substrate 1 and the conductive region 4.

The electromagnetic waves arrive in the Z direction, and are incident on the conductive region 4. Assuming that the electric field of the arriving electromagnetic waves is oriented to the positive X direction and the positive Y direction is perpendicular to the X and Z directions, the electric field shown by an electric flux line 5 is formed by the electromagnetic waves incident on the conductive region 4.

After the electric flux line 5 arrives at the low charge-density region 3, it is refracted at the fringe of the low charge-density region 3. The electric flux line 5 is oriented parallel to the propagation direction of the electromagnetic waves in a boundary between the high charge-density region 2 and the low charge-density region 3, that is, oriented vertical to a main surface of the semiconductor substrate 1, and is coupled to charges 6 in the high charge-density region 2.

As described above, a fringe electric field is formed at the fringe of the conductive region 4 with the electromagnetic waves having the electric field in the X direction incident on the electromagnetic wave reception device. With the fringe electric field being oriented to the Z direction around the boundary between the high charge-density region 2 and the low charge-density region 3, the incident electromagnetic waves are coupled to the charges 6 that have a density higher than that of the high charge-density region 2.

Next, the behaviors of the fringe electric field and the charges with the incident electromagnetic waves will be described.

(a) in FIG. 5 shows a graph of a distribution E_{z} (x) of Z components of electric intensity of the fringe electric field in the X direction immediately after the electromagnetic waves are incident. (a) in FIG. 5 illustrates respective positions of the high charge-density region 2 and the low charge-density region 3 in the X direction to facilitate the understanding.

The electric field is concentrated around the boundary between the high charge-density region 2 and the low charge-density region 3 (x₁≦x≦x₂), and the electric field intensity is the highest.

(b) in FIG. 5 shows a graph of an energy level distribution E_{c} (x) of electrons in the X direction, where the energy level occurs because of the electric field intensity distribution. In (b) in FIG. 5, a solid line illustrates the distribution of the energy level of electrons immediately after the electromagnetic waves are incident, and a dashed line illustrates the distribution before the electromagnetic waves are incident.

Immediately after the electromagnetic waves are incident, the energy level E_{c} (x) of electrons is the lowest at the boundary between the high charge-density region 2 and the low charge-density region 3, where the electric intensity E_{Z} (x) in (a) in FIG. 5 is the highest. In contrast, the energy level E_{c} (x) around the boundary (x₁≦x≦x₂) is lower than a value before the electromagnetic waves are incident.

(c) in FIG. 5 shows a graph of a distribution n (x) of the electron densities in the X direction, with the variations in the energy level of electrons. In (c) of FIG. 5, a solid line illustrates the distribution of the electron densities immediately after the electromagnetic waves are incident, and a dashed line illustrates the distribution before the electromagnetic waves are incident.

Immediately after the electromagnetic waves are incident, the distribution n (x) of the electron density is higher than that before the electromagnetic waves are incident, around the boundary between the high charge-density region 2 and the low charge-density region 3, where the energy level E_{c} (x) of electrons in (b) in FIG. 5 is lower.

Thus, the fringe electric field occurring at the fringe of the conductive region 4 is coupled to the electrons in the high charge-density region 2 and modulates the density distribution of the electrons. Furthermore, since the fringe electric field extends to the low charge-density region 3, the electrons in the high charge-density region 2 overflow to the low charge-density region 3 around the boundary.

The electromagnetic wave reception device according to an implementation in the present invention receives the incident electromagnetic waves, by detecting the electrons overflowing from the high charge-density region 2 to the low charge-density region 3 using a charge detecting device (not illustrated in FIG. 4) connected to the low charge-density region 3.

Here, since the incident electromagnetic waves oscillate at the higher frequency, the electric field intensity varies as the time passes.

The following describes a method of detecting the overflowing charges as the time passes.

Since a wavefront of electromagnetic waves is successively incident as the time passes, the fringe electric field propagates through the insulation region 7 in a direction (minus X direction) apart from the boundary between the high charge-density region 2 and the low charge-density region 3 while it is coupled to the charges on the underside of the conductive region 4 and the charges 6 in the high charge-density region 2. In addition, the electric field intensity distribution E_{Z} (x), the energy level distribution E_{c} (x) of electrons, and the electron density distribution n (x) temporally vary.

Assuming the time immediately after the electromagnetic waves are incident as t=0, (a), (b), and (c) in FIG. 5 respectively correspond to E_{Z} (x), E_{c} (x), and n (x) in a state where the electric field intensity E_{Z} (x=0) takes the largest positive value at the fringe of the conductive region 4 at t=0.

Assuming the frequency of electromagnetic waves as T,

(a), (b), and (c) in FIG. 6 respectively illustrate E_{Z} (x), E_{c} (x), and n (x) in a state where the electric field intensity E_{Z} (x=0) takes a positive mean value at t=T/8.

(a), (b), and (c) in FIG. 7 respectively illustrate E_{Z} (x), E_{c} (x), and n (x) in a state where E_{Z} (x=0) takes a value of zero at t=T/4.

(a), (b), and (c) in FIG. 8 respectively illustrate E_{Z} (x), E_{c} (x), and n (x) in a state where E_{Z} (x=0) takes a negative mean value at t=3T/8.

(a), (b), and (c) in FIG. 9 respectively illustrate E_{Z} (x), E_{c} (x), and n (x) in a state where E_{Z} (x=0) takes the largest negative value at t=T/2.

As clear from (a), (b), and (c) in FIG. 5, when the electric field intensity E_{Z} (x=0) takes the largest positive value at the fringe, the potential at the fringe is the highest, and thus a charge density n (x=0) is also the highest. Here, the charge density is equivalent to the electron density.

The fringe electric field overflows to the low charge-density region 3 around the fringe. With the overflowing, the electrons overflow from the high charge-density region 2 to the low charge-density region 3. Since the charge density in the low charge-density region 3 is lower than that in the high charge-density region 2, the electrons overflowing from the high charge-density region 2 flow, as a diffusion current, toward the low charge-density region 3 having the lower charge density.

Furthermore, as illustrated in (a), (b), and (c) in FIG. 9, when the electric field intensity E_{Z} (x=0) takes the largest negative value, the energy level E_{c} (x=0) of electrons at the fringe is the highest, and the charge density in the high charge-density region 2 is the lowest. Since the charge density in the low charge-density region 3 is originally lower, the diffusion of electrons in a reverse direction from the low charge-density region 3 to the high charge-density region 2 is negligible.

Thus, the overflow of electrons from the high charge-density region 2 to the low charge-density region 3 is an essentially irreversible process, and temporally averaging the diffusion current produces a DC current flowing from the low charge-density region 3 to the high charge-density region 2.

As a result, connecting a charge detecting device to the low charge-density region 3 can detect charges flowing as the diffusion current. In other words, the incident electromagnetic waves can be detected as charges.

As described above, the electromagnetic wave reception device according to an implementation in the present invention generates the fringe electric field in a direction vertical to a propagation direction of electromagnetic waves from the fringe of the conductive region 4, using the electric field of the electromagnetic waves oscillated vertical to the propagation direction. With the coupling of the fringe electric field to the charge density distribution in the semiconductor substrate 1, the electromagnetic wave reception device detects the charges transferred with the density distribution. The charges can be detected by known methods, for example, a method of detecting the variations in voltages using a charge-voltage converter (capacitor, such as a floating diffusion).

Thereby, unlike the case where the terahertz waves are detected as photons, there is no need to place the electromagnetic wave reception device at a lower temperature, which substantially facilitates the usage of the electromagnetic wave reception device. Furthermore, the electromagnetic wave reception device can be downsized because it does not use any antenna for receiving the terahertz waves as radio waves and the size solely depends on the typical length of the spatial density distribution of charges. Thereby, since the dependency of the sensitivity on a frequency according to a length of the antenna is eliminated, the present invention allows the electromagnetic wave reception device to operate in a wider frequency range.

### Embodiment 2

An electromagnetic wave reception device according to Embodiment 2 in the present invention will be described with reference to FIGS. 10 to 16. Embodiment 2 specifically describes a structure of the electromagnetic wave reception device in the present invention in the case where it is implemented on a semiconductor substrate.

FIG. 10 illustrates a top view of a layout example of the electromagnetic wave reception device on the semiconductor substrate according to Embodiment 2.

The electromagnetic wave reception device in FIG. 10 includes a high charge-density region 2, a low charge-density region 3, a conductive region 4, a bias supply 402, a transfer gate 403, a floating diffusion (FD) 404, a field effect transistor (FET) 405, a transfer signal generator circuit 409, and a reset circuit 410. The high charge-density region 2 and the conductive region 4 are respectively hatched to readily recognize each region.

The high charge-density region 2 and the low charge-density region 3 are p-type Si regions (hereinafter referred to as p-type regions) formed on the semiconductor substrate. The portion of the high charge-density region 2 to be the p-type region is covered with the conductive region 4 via an insulation region.

The bias supply 402 applies a bias voltage to the conductive region 4. Setting the applied bias voltage to a voltage not smaller than a predetermined positive threshold results in a formation of an inversion layer made of high-density electrons in the p-type region under the conductive region 4.

The inversion layer functions as the high charge-density region 2. A portion in the p-type region where the bias voltage is not applied, in other words, a portion that is not covered with the conductive region 4 functions as the low charge-density region 3.

Such a structure corresponds to the fundamental structure of the electromagnetic wave reception device as described in Embodiment 1.

The transfer gate 403 transfers the charges accumulated in the low charge-density region 3 to the FD 404. The FD 404 includes a p-n junction, and temporarily holds the charges transferred from the low charge-density region 3.

In the FET 405 that functions as a source follower, a drain terminal 406 is connected to a power supply that is not illustrated and feeds, to a gate 407, an output voltage corresponding to the charges in the FD 404. Then, a source terminal 408 provides a voltage corresponding to the variation in the drain current.

The transfer signal generator circuit 409 generates a signal for controlling on and off of the transfer gate 403. The reset circuit 410 includes a reset transistor that resets the charges accumulated in the low charge-density region 3 and the FD 404.

FIG. 11 is a cross-section view illustrating a section A-A′ of the electromagnetic wave reception device in FIG. 10.

In FIG. 11, a p-type region 51 is formed on a semiconductor substrate 1 by ion implantation. An n-type region 52 is formed in the p-type region 51 by arsenic ion implantation. The vicinity of the n-type region 52 remains unaffected as the p-type region 51.

The insulation region 7 made of SiO₂ is formed on the p-type region 51 by a thermal oxidation method. In the formation, the insulation region 7 under the conductive region 4 has a thickness of 5 nm, and other portions of the conductive region 4 has a thickness of 100 nm.

A positive voltage that is not smaller than a predetermined threshold is applied to the conductive region 4 through the bias supply 402 in FIG. 10. As a result, an inversion layer having high-density electrons is formed immediately under the conductive region 4. As described above, the inversion layer functions as the high charge-density region 2. The portions where no inversion layer is formed within the p-type region 51 functions as the low charge-density region 3.

Next, the energy level in the main section of the electromagnetic wave reception device having such a structure will be described.

FIG. 12 illustrates a band diagram in a section B-B′ in FIG. 11.

The diagram in FIG. 12 illustrates an occupied level 61 of the conductive region 4, a Fermi level 62 that is the highest energy level of the occupied level 61, a potential barrier 63 formed by the insulation region 7, a bottom 64 of a conduction band in the p-type region 51, the highest energy level 65 of a valence band in the p-type region 51, and an electron energy level 66 in the inversion layer.

FIG. 13 illustrates a band diagram in a section C-C′ in FIG. 11. The energy levels are shown by the same numerals as in FIG. 12, and thus the description will be omitted.

The section C-C′ shows a potential well described by the lowest energy level 67 in the n-type region 52, with the formation of a p-n junction in a boundary between the p-type region 51 and the n-type region 52 maintained in the vicinity of the p-type region 51. The energy level in the p-type region 51 described by a curve increases as it separates from the potential well.

FIG. 14 illustrates a band diagram in a section D-D′ in FIG. 11, that is, in a boundary between the insulation region 7 and the p-type region 51. The energy levels are shown by the same numerals as in FIG. 12, and thus the description will be omitted.

The high charge-density region 2 is an inversion layer formed in the p-type region 51, and the low charge-density region 3 does not include the inversion layer formed in the p-type region 51.

Next, the processes where the electromagnetic waves incident on the electromagnetic wave reception device having such a structure are detected as signals will be described hereinafter.

In the case where the electromagnetic waves having electric field components oscillating in the X direction are incident on the electromagnetic wave reception device in FIG. 10 from a front side to a back side of the plane of paper, the detection processes are divided into the next 3 steps.

(First step) The electrons are injected from the high charge-density region 2 to the low charge-density region 3.

With the structure described in Embodiment 1, the electric field of the electromagnetic waves whose oscillation direction is converted into the Z direction is coupled to the electrons in the high charge-density region 2, at the fringes of the conductive region 4. Thereby, the density of the electrons in the high charge-density region 2 is modulated in the X direction. Furthermore, the electrons overflow into a portion in the p-type region 51 that is not covered with the conductive region 4, and are injected into the low charge-density region 3. The processes are expressed by an arrow 55 in FIG. 11.

(Second step) The electrons overflowing into the low charge-density region 3 are confined in the n-type region 52.

With the electromagnetic waves incident for a predetermined period of time, the electrons overflowing from the high charge-density region 2 to the low charge-density region 3 are diffused into a region within the low charge-density region 3 where the density is lower. The current induced by the diffusion flows in the low charge-density region 3 as a drift current with the band bending on a surface of the low charge-density region 3, and the electrons are confined in the n-type region 52 that functions as a potential well. The processes are expressed by an arrow 56 in FIG. 11.

(Third step) The electrons accumulated in the n-type region 52 are detected.

The electrons accumulated in the n-type region 52 are transferred to the FD 404 by turning on the transfer gate 403, and are read through the FET 405 as the source follower.

FIG. 15 is an equivalent circuit diagram illustrating the functional structure of the electromagnetic wave reception device according to an implementation in the present invention, in comparison with the conventional technique.

In FIG. 15, an antenna 91 represents a function of collecting the incident electromagnetic waves obtained by coupling of the electric field of electromagnetic waves whose oscillation direction is converted by the conductive region 4 to the charge density in the high charge-density region 2.

A diode 92 represents the electrons irreversibly transferring from the high charge-density region 2 to the low charge-density region 3. A diode 93 represents a potential well with a p-n junction formed in a boundary between the p-type region 51 and the n-type region 52.

The transfer gate 403, the FD 404, the FET 405, the transfer signal generator circuit 409, and the reset circuit 410 are respectively represented by circuit symbols with the corresponding numerals. The signal provided by the FET 405 is processed by a signal processing circuit that is not illustrated.

FIG. 16 is a graph showing a dependency of an S/N ratio of a reception signal to a bias voltage V_{g} to be applied to the conductive region 4, in the electromagnetic wave reception device.

As illustrated in FIG. 16, although the S/N ratio is very low while the bias voltage V_{g} is low, the S/N ratio increases in proportion to the increase in the bias voltage V_{g}. This results from the increase in the coupling efficiency of the incident electromagnetic waves to the charge density of the high charge-density region 2 and the increase in an amount of charges injected into the low charge-density region 3, along with the increase in the charge density in the high charge-density region 2 in proportion to the increase in the bias voltage V_{g}.

Furthermore, in a region in a range V_{g}≧2.0 V where the high charge-density region 2 reaches a saturated electron density, the S/N ratio also tends to be saturated along with the saturated electron density. Thus, desirably, the bias supply 402 may be used as a variable voltage source, and the bias voltage at which the high charge-density region 2 exactly reaches a saturated electron density may be applied to the conductive region 4.

### Embodiment 3

An electromagnetic wave reception device according to Embodiment 3 in the present invention will be described with reference to FIG. 17. Embodiment 3 describes a structure of the electromagnetic wave reception device that can obtain a higher S/N ratio.

FIG. 17 illustrates a top view of a layout example of the electromagnetic wave reception device on a semiconductor substrate according to Embodiment 3. The constituent elements described in Embodiment 2 will be denoted by the same numerals, and the description will be omitted in Embodiment 3 (see FIG. 10). The alphabetical character at the end of each numeral is for distinguishing from the constituent elements of the same type.

In the electromagnetic wave reception device in FIG. 17, low charge-density regions 3a and 3b are disposed to sandwich the conductive region 4 and the high charge-density region 2 immediately under the conductive region 4. FIG. 17 explicitly illustrates a power supply 1102 and a signal processing circuit 1101. Furthermore, FIG. 17 illustrates a bias supply 402a used as a variable voltage source, instead of the bias supply 402 in FIG. 10.

The electrons accumulated in the low charge-density regions 3a and 3b are transferred to FDs 404a and 404b, respectively. Then, FETs 405a and 405b respectively read signal voltages corresponding to the amount of charges accumulated in the FDs 404a and 404b.

Here, the length of the conductive region 4 is set to 0.2 μm. The setting is due to the following reason.

Assumed in the electromagnetic wave reception device according to Embodiment 3 is reception of electromagnetic waves in a frequency range centered on a frequency of 1 THz, and a voltage higher than a threshold by 1 V is applied to the conductive region 4 (gate). The half-wave length of 1-THz plasma generated from the electrons in the high charge-density region 2 can be obtained by Equation 1 (NPL 8).

$$\begin{matrix}[ Math 1 ] & \\ L = \frac{1}{2 f} \sqrt{\frac{e \cdot ( {V}_{g} - {V}_{t} )}{{m}^{*}}} & ( Equation 1 )\end{matrix}$$

Equation 1 yields L=0.2 μm when V_{g}−Vₜ=1.0 V, where f denoting the frequency of the electromagnetic waves to be received is 1 THz, e denotes elementary electric charges, V_{g} denotes a gate voltage, Vₜ denotes a threshold voltage, and m* denoting an effective mass of electrons is (0.26×9.1×10⁻³¹) kg.

The standing waves of plasmon arise due to the resonance with the electromagnetic waves in the frequency of 1 THz in the high charge-density region 2, by setting the length of the conductive region 4 to L=0.2 μm that is the half-wave length of 1-THz plasma generated from the electrons in the high charge-density region 2.

Since the incident electromagnetic waves are directly coupled to the electrons in the high charge-density region 2 through the fringe electric field in each boundary between the high charge-density region 2 and the low charge-density region 3 that is either side of the conductive region 4, each of the boundaries satisfy a free end boundary condition.

Thus, since the plasmons by the electrons in the high charge-density region 2 form the standing waves having the anti-nodes respectively in the two boundaries, the variations in the plasmons and the amount of charges injected from the high charge-density region 2 to the low charge-density region 3 are maximized.

With such a structure, the electromagnetic wave reception device according to Embodiment 3 maximizes the amount of charges injected into the low charge-density region 3 by generating the standing waves of the plasmons in the high charge-density region 2. Furthermore, the electromagnetic wave reception device can triple the S/N ratio implemented by the electromagnetic wave reception device according to Embodiment 2 having the same size as that of the electromagnetic wave reception device according to Embodiment 3, with the addition of output signals obtained from the charges injected from the two boundaries.

### Embodiment 4

An electromagnetic wave reception device according to Embodiment 4 in the present invention will be described with reference to FIG. 18. Embodiment 4 describes a structure of the electromagnetic wave reception device that can obtain a higher S/N ratio.

FIG. 18 illustrates a top view of a layout example of the electromagnetic wave reception device on a semiconductor substrate according to Embodiment 4. The constituent elements described in Embodiments 2 and 3 will be denoted by the same numerals, and the description will be omitted in Embodiment 4 (see FIGS. 10 and 17). The alphabetical character at the end of each numeral is distinguished from the constituent elements of the same type.

Low charge-density regions 3a to 3g and conductive regions 4a to 4f are alternately arranged in the electromagnetic wave reception device of FIG. 18. Under the conductive regions 4a to 4f, high charge-density regions 2a to 2f are respectively formed. Furthermore, the low charge-density regions 3a to 3g are respectively connected to FDs 404a to 404g through a transfer gate 403.

The low charge-density regions 3b to 3f between the conductive regions 4a to 4f can respectively accumulate the electrons injected from adjacent two of the high charge-density regions 2a to 2f.

The outputs of the FDs 404a to 404g are separately read by corresponding FET 405a to 405g, provided to a signal processing circuit 1103, and are summed. As such, the detection of electrons injected from multiple boundaries reduces the influence of, for example, scattering of electrons in the charge density distribution, increases the intensity of the signals, and increases the S/N ratio upon reception of the electromagnetic waves.

Here, the length L in the X direction of each of the conductive regions 4a to 4f and the low charge-density regions 3a to 3g is all set to 0.2 μm as described in Embodiment 3, so that the frequency is optimized for receiving the electromagnetic waves at 1 THz in a state where the bias voltage higher than the threshold by 1 V is applied to the conductive regions 4a to 4f.

With such a structure, the electromagnetic wave reception device according to Embodiment 4 can achieve an S/N ratio approximately 15 times higher than the one achieved by the electromagnetic wave reception device according to Embodiment 1, with the increase in the number of boundaries that can overflow electrons and the effect of plasma resonance.

### Embodiment 5

An electromagnetic wave reception device according to Embodiment 5 in the present invention will be described with reference to FIG. 19. Embodiment 5 describes a structure of the electromagnetic wave reception device that can detect electric field components included in the incident electromagnetic waves and having different oscillation directions.

FIG. 19 illustrates a top view of a layout example of the electromagnetic wave reception device on a semiconductor substrate according to Embodiment 5. The constituent elements described in Embodiment 3 will be denoted by the same numerals, and the description will be omitted in Embodiment 5 (see FIG. 17). The alphabetical character at the end of each numeral is distinguished from the constituent elements of the same type.

The electromagnetic wave reception device in FIG. 19 includes the conductive region 4 that is a square. The high charge-density region 2 that is also square is formed immediately under the square conductive region 4.

Low charge-density regions 3a and 3b are adjacent to the high charge-density region 2 at the perpendicular two sides, and thus are electrically separated from each other. Each of the low charge-density regions 3a and 3b includes an n-type region that is a potential well for respective electrons (not illustrated).

The electrons accumulated in the low charge-density regions 3a and 3b are transferred to FDs 404a and 404b through transfer gates 403a and 403b, respectively. Then, the FETs 405a and 405b respectively read signal voltages corresponding to the amount of charges accumulated in the FDs 404a and 404b, and the signal voltages are fed to a signal processing circuit 1104.

The charges accumulated in the low charge-density region 3a are charges injected from the high charge-density region 2 with the electric field components oscillating in the X direction. The charges accumulated in the low charge-density region 3b are charges injected from the high charge-density region 2 with the electric field components oscillating in the Y direction. Thus, the electromagnetic wave reception device according to Embodiment 5 can independently receive two polarized waves perpendicular to each other.

The signal processing circuit 1104 adds the signal voltages from the FETs 405a and 405b, thus achieving an S/N ratio higher than the one obtained when only oscillation components in a single direction are received.

Furthermore, the signal processing circuit 1104 calculates a difference between outputs of the FETs 405a and 405b, thus detecting a difference between the two electric field components that are included in the incident electromagnetic waves and perpendicular to each other, as a phase of the electromagnetic waves.

### Embodiment 6

An imaging device according to Embodiment 6 in the present invention will be described with reference to FIG. 20. The imaging device according to Embodiment 6 includes a plurality of pixels which are arranged in a two-dimensional array and each of which is one of the electromagnetic wave reception devices described hereinbefore.

FIG. 20 is a block diagram illustrating a functional structure of the imaging device according to Embodiment 6. Each pixel is represented by the equivalent circuit diagram of the electromagnetic wave reception device described in Embodiment 2 and in FIG. 15, for example.

In the imaging device in FIG. 20, a readout circuit reads an output signal from the electromagnetic wave reception device in each of the pixels to an output terminal 149. The readout circuit includes a vertical scanning circuit 141, a horizontal scanning circuit 142, row selection lines 1431 and 1432, column signal lines 1441 and 1442, row selection transistors 1451 to 1454 arranged in each of the pixels, column selection transistors 1461 and 1462 arranged in each column, a horizontal signal line 147, and an output stage amplifier 148.

After electromagnetic waves are incident on the imaging device for a predetermined period of time, the electrons confined in potential wells (denoted as diodes 93) in each of the pixels are transferred to FDs 404 through transfer gates 403, and signal voltages corresponding to the amount of charges accumulated in the FDs 404 are provided from FETs 405.

The vertical scanning circuit 141 sequentially selects each row, and provides a selection signal to a row selection line of the selected row. For example, when the selection signal is provided to the row selection line 1431, the row selection transistors 1451 and 1452 that are arranged in each of the pixels of the corresponding rows are brought into conduction. Accordingly, a pixel output signal in a row corresponding to the row selection line 1431 is provided to each of the corresponding column signal lines 1441 and 1442, and is ready to be provided to the horizontal signal line 147.

Next, the horizontal scanning circuit 142 sequentially selects the column selection transistors 1461 and 1462 in each column, so that the output stage amplifier 148 amplifies the signal of the corresponding column and the output terminal 149 provides the amplified signal as a time series output signal.

With such a structure, the imaging device can obtain a two-dimensional image signal of the electromagnetic waves.

FIG. 21 is a graph showing a wavelength dependency of the incident electromagnetic waves to an S/N ratio of an output signal in the imaging device.

The imaging device has reception sensitivity to the electromagnetic waves according to the principle described in Embodiment 1. Moreover, it has reception sensitivity to electromagnetic waves in a wider wavelength range with the use of general electromagnetic phenomenon of the conductive region 4 and the high charge-density region 2.

Furthermore, since the diodes 93 as the potential wells have the same structures as conventional photodiodes, they function as detectors of photons having energy not smaller than the band-gap energy of Si substrates, and have sensitivity in a wavelength range corresponding to the energy. Thus, although the imaging device is a single device, it has the sensitivity to the electromagnetic waves in a wider bandwidth ranging from visible light, far infrared radiation, and THz radiation.

As stated above, although the image sensor and the electromagnetic wave reception device in the present invention described based on Embodiments, the present invention is not limited to such Embodiments. Any modification conceived by a person with an ordinary skill in the art without departing from the gist of the present invention is included in the scope of the present invention.

### INDUSTRIAL APPLICABILITY

The electromagnetic wave reception device and the imaging device according to the present invention are applicable to, for example, a security check device, a food inspection device, an atmospheric sensor, and a medical diagnosis device.

### REFERENCE SIGNS LIST

1 Semiconductor substrate
2, 2a to 2f High charge-density region
3, 3a to 3g Low charge-density region
4, 4a to 4f Conductive region
5 Electric flux line
6 Charges
7 Insulation region
51 P-type region
52 N-type region
55, 56 Arrow
61 Occupied level
62 Fermi level
63 Potential barrier
64 Bottom of a conduction band
65 Highest energy level of a valence band
66 Electron energy level in an inversion layer
67 Energy level in an n-type region
91 Antenna
92, 93 Diode
141 Vertical scanning circuit
142 Horizontal scanning circuit
147 Horizontal signal line
148 Output stage amplifier
149 Output terminal
201 Antenna
202 Amplifier circuit
203 Detection circuit
204 Signal processing circuit
211 Femtosecond laser light source
212 Beam splitter
213 Pump light
214 Probe light
215 Light delay line
216, 223 Mirror
217 Photoconductive switch
218 Test object
219 Transmission component of terahertz waves
220 Lens
221 Half mirror
222 Electric field modulator
224 Beam expander
225 Probe light having a beam radius expanded
226 Light polarizer
227 Photo detector
402 Bias supply
403, 403a, 403b Transfer gate
404, 404a to 404g FD
405, 405a to 405g FET
406, 406a, 406b Drain terminal
407, 407a, 407b Gate
408, 408a, 408b Source terminal
409 Transfer signal generator circuit
410, 410a, 410b Reset circuit
1101, 1103, 1104 Signal processing circuit
1102, 1102a, 1102b Power supply
1431, 1432 Row selection line
1441, 1442 Column signal line
1451 to 1454 Row selection transistor
1461, 1462 Column selection transistor
2201 Substrate
2202 Source
2203 Drain
2204 Electron donor layer
2207 Two dimensional electron gas
2208 Laser light
2251, 2252, 2253, 2261, 2262, 2263 Gate

1. An electromagnetic wave reception device that obtains charges according to an electric field of electromagnetic waves incident on a semiconductor substrate, said device comprising:
at least one first region provided on the semiconductor substrate and having a first charge density;
a conductive region covering said first region via an insulation region; and
at least one second region provided adjacent to said first region on the semiconductor substrate and having a second charge density lower than the first charge density,
wherein said second region is connected to a charge detecting circuit.

2. The electromagnetic wave reception device according to claim 1,
wherein a thickness of said conductive region is greater than a skin depth of the electromagnetic waves incident on said conductive region.

3. The electromagnetic wave reception device according to claim 1,
wherein a potential well for charges in said first region is formed in said second region.

4. The electromagnetic wave reception device according to claim 3,
wherein the charges in said first region have a polarity opposite to a polarity of majority carriers in said second region, and
majority carriers in the potential well have a polarity identical to the polarity of the charges in said first region.

5. The electromagnetic wave reception device according to claim 1,
wherein said conductive region is connected to a variable voltage source.

6. The electromagnetic wave reception device according to claim 1,
wherein a plurality of said first regions and a plurality of said second regions are alternately arranged,
said conductive region is disposed on each of said first regions, and
said second regions are connected to the charge detecting circuit.

7. The electromagnetic wave reception device according to claim 1,
wherein said first region has a width half a wavelength of a plasmon formed by the charges in said first region, in a direction perpendicular to a boundary with said second region.

8. The electromagnetic wave reception device according to claim 1,
wherein said first region and said second region are adjacent to each other at boundaries extending in different directions.

9. The electromagnetic wave reception device according to claim 8,
wherein two of the boundaries are perpendicular to each other.

10. An imaging device, comprising:
a plurality of said electromagnetic wave reception devices according to claim 1 that are arranged in a two-dimensional array; and
a readout unit configured to sequentially read output signals from said electromagnetic wave reception devices.

11. An electromagnetic wave reception device that obtains charges according to an electric field of electromagnetic waves incident on a semiconductor substrate, said device comprising
a conductive region covering a first region on the semiconductor substrate via an insulation region,
wherein a voltage is applied to said conductive region with reference to the semiconductor substrate, and
a second region is connected to a charge detecting circuit, said second region being adjacent to the first region on the semiconductor substrate and not being covered with said conductive region.

12. An electromagnetic wave reception method of obtaining charges according to an electric field of electromagnetic waves incident on a semiconductor substrate, said method comprising:
generating a fringe electric field at a fringe of a conductive region on the semiconductor substrate, with the electromagnetic waves incident on the conductive region;
transferring, between two regions on the semiconductor substrate, the charges with the fringe electric field generated at the fringe of the conductive region, the two regions having different charge densities; and
detecting the transferred charges.
